(19) United States
(12) Patent Application Publication
(10) Pub. No.: US 2025/0164566 A1
(43) Pub. Date: May 22, 2025

(54) BATTERY TERMINAL PROTECTION CIRCUIT AND BATTERY TERMINAL

(71) Applicant: Zhejiang Safemate Automative Safety & Emergency Technology Co., Ltd., Hangzhou (CN)

(72) Inventors: Zhonghua WU, Hangzhou (CN); Naixing WANG, Hangzhou (CN)

(73) Assignee: Zhejiang Safemate Automative Safety & Emergency Technology Co., Ltd., Hangzhou (CN)

(21) Appl. No.: 18/390,671

(22) Filed: Dec. 20, 2023

(30) Foreign Application Priority Data
Nov. 17, 2023 (CN) 202323098789.2

(51) Int. Cl. G01R 31/3835; G01R 31/36; H01M 50/543

(52) U.S. Cl. CPC G01R 31/3835; G01R 31/3646; H01M 50/543

(57) ABSTRACT

The disclosure relates to a battery terminal protection circuit and a battery terminal, which includes a main control circuit, a power supply circuit, a voltage detection circuit, a battery state display circuit and an engine state display circuit. The power supply circuit is coupled with the main control circuit and the power supply circuit further provides power supply for the main control circuit; the voltage detection circuit is coupled with the power supply circuit and the voltage detection circuit is further coupled with the main control circuit; the voltage detection circuit is configured to detect voltages of a battery and an engine; and the battery state display circuit and the engine state display circuit are both coupled with the main control circuit, which solves a problem that health of a battery and an engine cannot be determined when the battery terminal is used.

### CROSS REFERENCE TO THE RELATED APPLICATIONS

This Non-provisional application claims priority under 35 U.S.C. § 119 (a) on Chinese Patent Application No(s). CN 202323098789.2 filed on Nov. 17, 2023, the entire contents of which are hereby incorporated by reference.

### TECHNICAL FIELD

The disclosure relates to the technical field of automobile battery detection apparatus, in particular to a battery terminal protection circuit and a battery terminal.

### BACKGROUND ART

The battery terminal is a tool for emergency startup in automobile accessories. A traditional battery terminal serves as a connecting line between a startup power supply and an automobile battery when the startup power supply charges the automobile battery, in which a positive battery clamp (usually a black clamp) of the battery terminal is configured to clamp a negative electrode of the automobile battery, and a negative battery clamp (usually a red clamp) of the battery terminal is configured to clamp a positive electrode of the automobile battery, and another interface of the battery terminal is inserted into an interface of the startup power supply, and the automobile can be started up when a blue light on the battery terminal is always-on.

However, the battery terminal is used with a single function and no detection of a battery voltage and an engine voltage, and thus health of the battery and an engine cannot be known by an operator.

### SUMMARY

In view of shortcomings in related art, a battery terminal protection circuit and a battery terminal are provided in the disclosure, which solves a problem that health of a battery and an engine cannot be determined when the battery terminal is used.

In order to solve the above technical problem, the present disclosure provides following technical solutions.

A battery terminal protection circuit includes a main control circuit, a power supply circuit, a voltage detection circuit, a battery state display circuit and an engine state display circuit. The power supply circuit is coupled with the main control circuit and the power supply circuit further provides power supply for the main control circuit; the voltage detection circuit is coupled with the power supply circuit and the voltage detection circuit is further coupled with the main control circuit; the voltage detection circuit is configured to detect voltages of a battery and an engine; and the battery state display circuit and the engine state display circuit are both coupled with the main control circuit.

Alternatively, the voltage detection circuit includes a first resistor, a second resistor and a third resistor. The first resistor is connected in series with the second resistor, and the third resistor is connected in parallel with the second resistor.

Alternatively, the battery state display circuit includes three sets of first light emitting diodes connected in parallel, and emitting colors of the three sets of first light emitting diodes are different from each other.

Alternatively, the three sets of first light emitting diodes are further connected in parallel with a first voltage mode display circuit.

Alternatively, the engine state display circuit includes three sets of second light emitting diodes connected in parallel, and emitting colors of the three sets of second light emitting diodes are different from each other.

Alternatively, the three sets of second light emitting diodes are further connected in parallel with a second voltage mode display circuit.

Alternatively, the battery terminal protection circuit further includes a reverse connection alarm circuit, which is coupled with the main control circuit.

Alternatively, the battery terminal protection circuit further includes a voltage display circuit, which is coupled with the main control circuit.

Alternatively, the main control circuit is further connected with a voltage mode switching circuit.

A battery terminal includes the battery terminal protection circuit according to any one of the above, and further includes a housing, a cable and a clamp. The housing is arranged on the cable, the battery terminal protection circuit is installed in the housing, and a set of positive and negative clamps are provided at both ends of the cable respectively.

Compared with the related art, the technical schemes provided in the disclosure have following beneficial effects.

With provision of the voltage detection circuit, the battery voltage can be detected so as to enable the operator to know the health of the battery through the battery state display circuit. At the same time, the voltage detection circuit can also be configured to detect the engine voltage so as to enable the operator to know the health of the engine through the engine state display circuit.

### BRIEF DESCRIPTION OF THE DRAWINGS

In order to explain the embodiments of the present disclosure or the technical scheme in the prior art more clearly, the drawings required in the description of the embodiments or the prior art will be briefly introduced below; obviously, the drawings in the following description are only some embodiments of the present disclosure, and other drawings can be obtained according to these drawings by those of ordinary skill in the art without paying creative labor.

FIG. 1 is a circuit diagram of a main control circuit in a battery terminal protection circuit according to Embodiment 1;

FIG. 2 is a circuit diagram of a power supply circuit and a voltage detection circuit in the battery terminal protection circuit according to Embodiment 1;

FIG. 3 is a circuit diagram of a battery state display circuit and a first voltage mode display circuit in the battery terminal protection circuit according to Embodiment 1;

FIG. 4 is a circuit diagram of an engine state display circuit and a second voltage mode display circuit in the battery terminal protection circuit according to Embodiment 1;

FIG. 5 is a circuit diagram of a voltage display circuit in the battery terminal protection circuit according to Embodiment 1;

FIG. 6 is a circuit diagram of a reverse connection alarm circuit in the battery terminal protection circuit according to Embodiment 1;

FIG. 7 is a perspective view of a battery terminal according to Embodiment 2;

FIG. 8 is a design diagram of a surface of a housing of the battery terminal according to Embodiment 2.

### REFERENCE NUMERALS

1. Housing; 2. Cable; 3. Clamp; 4. Voltage Display Box; 5. Voltage Mode Change-over Switch; 6, 12 V Voltage Display Area; 7. 24 V Voltage Display Area; 8. Engine Health Display Area; 9. Battery Health Display Area; 10, Reverse Connection Alarm Display Area; 11. Main Control Circuit; 12. Power Supply Circuit; 13. Voltage Detection Circuit; 14. Battery State Display Circuit; 15. Engine State Display Circuit; 16. First Voltage Mode Display Circuit; 17. Second Voltage Mode Display Circuit; 18, Reverse Connection Alarm Circuit; 19. Voltage Display Circuit; 20. Voltage Mode Switching Circuit; 21. Rectifier Circuit.

### DETAILED DESCRIPTION

The present disclosure will be further described in detail with reference to the following examples which are explanation of the present disclosure and the present disclosure is not limited to the following examples.

### Embodiment 1

A battery terminal protection circuit includes a main control circuit 11, a power supply circuit 12, a voltage detection circuit 13, a battery state display circuit 14 and an engine state display circuit 15. The power supply circuit 12 is coupled with the main control circuit 11 and the power supply circuit 12 further provides power supply for the main control circuit 11; the voltage detection circuit 13 is coupled with the power supply circuit 12 and the voltage detection circuit 13 is further coupled with the main control circuit 11; the voltage detection circuit 13 is configured to detect voltages of a battery and an engine; and the battery state display circuit 14 and the engine state display circuit 15 are both coupled with the main control circuit 11.

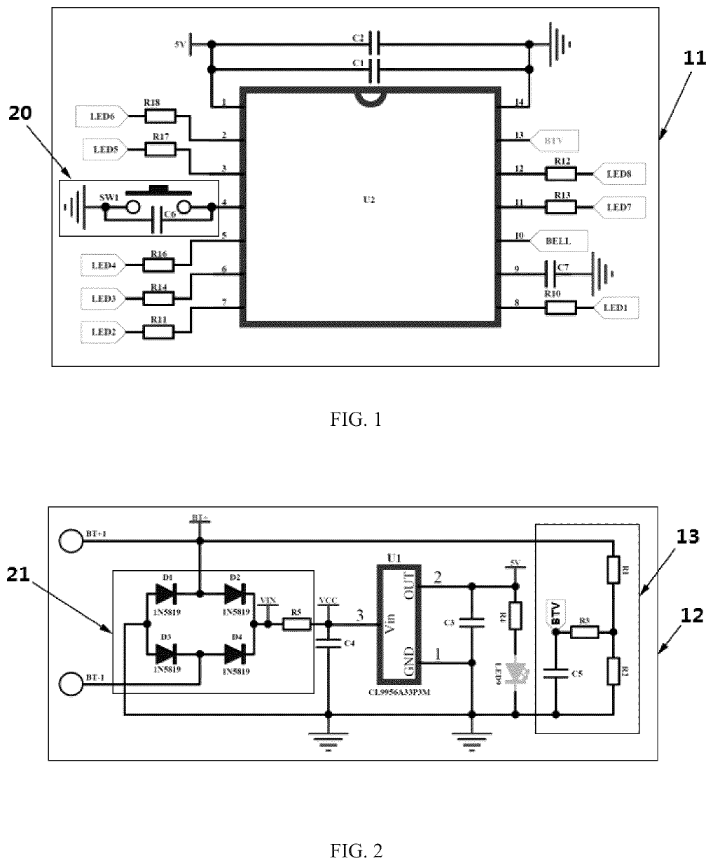

As shown in FIG. 1, the main control circuit 11 is implemented by a single-chip computer with a model of MDT10F and its attached circuit. At this time, the attached circuit is provided with a first capacitor C1 and a second capacitor C2 arranged in parallel between a pin 1 and a pin 14 of the MDT10F chip, and the pin 1 is connected with a 5 V voltage, and the pin 14 is grounded. The power supply circuit 12 is configured for supplying power to the single-chip computer. As shown in FIG. 2, the power supply circuit 12 includes a power supply chip with a model of CL9956A33P3M, an input terminal of the power supply chip is connected with a rectifier circuit 21, a grounding terminal of the power supply chip is grounded, a third capacitor C3 is provided between an output terminal and the grounding terminal of the power supply chip, a fourth resistor R4 is connected in parallel with the third capacitor C3, and a third light-emitting diode LED 9 is connected in series with the fourth resistor R4 for displaying a power-on state.

The rectifier circuit 21 includes a first diode D1, a second diode D2, a third diode D3 and a fourth diode D4. An output terminal of the first diode D1 is connected with an input terminal of the second diode D2, an input terminal of the first diode D1 is connected with an input terminal of the third diode D3, an output terminal of the third diode D3 is connected with an input terminal of the fourth diode D4, and an output terminal of the second diode D2 is connected with an output terminal of the fourth diode D4, the output terminal of the first diode D1 is further connected with a power positive electrode, the output terminal of the third diode D3 is connected with a power negative electrode, the input terminals of the first diode D1 and the third diode D3 are further grounded, the output terminals of the second diode D2 and the fourth diode D4 are connected with the fifth resistor R5 and then connected to the input terminal of the power supply chip, and the fifth resistor R5 is further connected with a fourth capacitor C4.

As shown in FIG. 2, the voltage detection circuit 13 includes a first resistor R1, a second resistor R2 and a third resistor R3. The first resistor R1 is connected in series with the second resistor R2, the third resistor R3 is connected in parallel with the second resistor R2, and a fifth capacitor C5 is connected in series across the third resistor R3.

At this time, detection principle of the voltage detection circuit 13 is that a voltage can be controlled within a detectable range of the single-chip computer through series voltage division of the first resistor R1, the second resistor R2 and the third resistor R3, and the single-chip computer can calculates an actual voltage from a detected voltage.

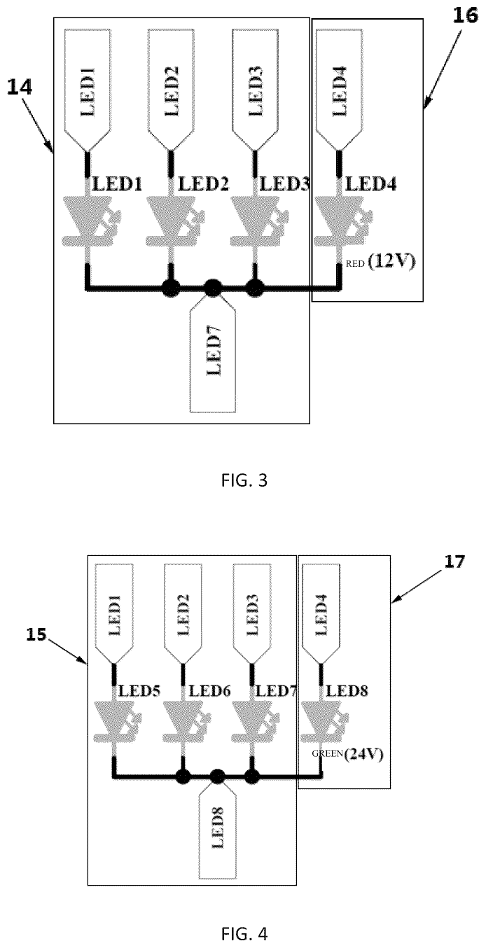

On the other hand, as shown in FIG. 3, the battery state display circuit 14 includes three sets of first light-emitting diodes connected in parallel, and emitting colors of the three sets of first light-emitting diodes are different from each other, which can be any color such as a red color, a green color, a blue color, an orange color, etc. Input terminals of the three sets of first light-emitting diodes are respectively connected to pins 8, 7 and 6 of the single-chip computer, and the three sets of first light-emitting diodes are also connected in parallel with a first voltage mode display circuit 16. The first voltage mode display circuit 16 includes a fourth light emitting diode LED 4, which is configured to light up when the circuit is at a voltage of 12 V. An input terminal of the fourth light emitting diode LED 4 is connected with a pin 5 of the single-chip computer, and output terminals of the three sets of first light-emitting diodes and the fourth light-emitting diode LED 4 are connected with a pin 11 of the single-chip computer.

As shown in FIG. 4, the engine state display circuit 15 includes three sets of second light-emitting diodes connected in parallel, and emitting colors of the three sets of second light-emitting diodes are different from each other, which can be any color such as a red color, a green color, a blue color, an orange color, etc. Input terminals of the three sets of second light-emitting diodes are respectively connected to the pins 8, 7 and 6 of the single-chip computer, and the three sets of second light-emitting diodes are also connected in parallel with a second voltage mode display circuit 17. The second voltage mode display circuit 17 includes a fifth light emitting diode LED 8, which is configured to light up when the circuit is at a voltage of 24 V. An input terminal of the fifth light emitting diode LED 8 is connected with the pin 5 of the single-chip computer, and output terminals of three sets of second light-emitting diodes and the fifth light-emitting diode 4 are connected with a pin 12 of the single-chip computer.

Therefore, a battery health detection function is realized with above circuit arrangement. Specifically, when a product is connected correctly, the voltage detection circuit 13 can acquire a battery voltage.

When a circuit voltage is at a level of 12 V (the fourth light-emitting diode LED 4 lights up), if the battery voltage is less than 11.7 V, it indicates a bad battery, and an indicator, a first light-emitting diode LED 1, lights up; if the battery voltage is between 11.8 V and 12.3 V, it indicates that the battery needs to be charged, and an indicator, a first light-emitting diode LED 2, lights up; and if the battery voltage is between 12.4 V and 12.6 V, it indicates that the battery is fully charged, and an indicator, a first light-emitting diode LED 3, lights up.

When the circuit voltage is at a level of 24 V (the fifth light-emitting diode LED 8 lights up), if the battery voltage is less than 23.4 V, it indicates a bad battery, and an indicator, a first light-emitting diode LED 1, lights up; if the battery voltage is between 23.5 V and 24.6 V, it indicates that the battery needs to be charged, and an indicator, a first light-emitting diode LED 2, lights up; and if the battery voltage is between 24.7 V and 25.2 V, it indicates that the battery is fully charged, and an indicator, a first light-emitting diode LED 3, lights up.

Therefore, the battery health can be displayed by setting of a battery health detection range and combining the voltage detection circuit 13 and the battery status display circuit 14.

On the other hand, the engine health detection function can be realized in this embodiment. Specifically, after the automobile is started up, the engine operates and the voltage rises, and at this time, the voltage detection circuit 13 acquires an engine voltage.

When a circuit voltage is at a level of 12 V (the fourth light-emitting diode LED 4 lights up), if the engine voltage is between 12.6 V and 13.2 V, it indicates low power of the engine, and an indicator, a second light-emitting diode LED 5, lights up; if the engine voltage is between 13.3 V and 14.8 V, it indicates that the engine is normal, and an indicator, a second light-emitting diode LED 6, lights up; and if the engine voltage is between 14.9 V and 16 V, it indicates that the engine voltage is too high, and an indicator, a second light-emitting diode LED 7, lights up.

When the circuit voltage is at a level of 24 V (the fifth light-emitting diode LED 8 lights up), if the engine voltage is between 25.2 V and 26.5 V, it indicates low power of the engine, and an indicator, a second light-emitting diode LED 5, lights up; if the engine voltage is between 26.6 V and 29.6 V, it indicates that the engine is normal, and an indicator, a second light-emitting diode LED 6, lights up; and if the engine voltage is between 29.7 V and 32 V, it indicates that the engine voltage is too high, and an indicator, a second light-emitting diode LED 7, lights up.

Therefore, in this embodiment, the engine health can be displayed by setting of an engine health detection range and combining the voltage detection circuit 13 with the engine status display circuit 15. Meanwhile, according to principle that the engine voltage must be higher than the battery voltage, a same voltage detection circuit 13 can be commonly used for the battery and engine health status detection, which reduces waste of resources compared with separate setting of detection circuits.

For voltage level adjustment of the circuit voltage, it is realized by connecting a voltage mode switching circuit 20 to the main control circuit 11 in this embodiment. Specifically, the voltage mode switching circuit 20 includes a switch SW1 and a sixth capacitor C6 connected in parallel across the switch SW1. One end of the switch SW1 is connected to the pin 4 of the single-chip computer, and the other end of the switch SW1 is grounded. When the switch SW1 is turned on, a voltage mode is switched to a level of 12 V, and when the switch SW1 is closed, the voltage mode is switched to a level of 24 V, thus making the whole circuit more applicable.

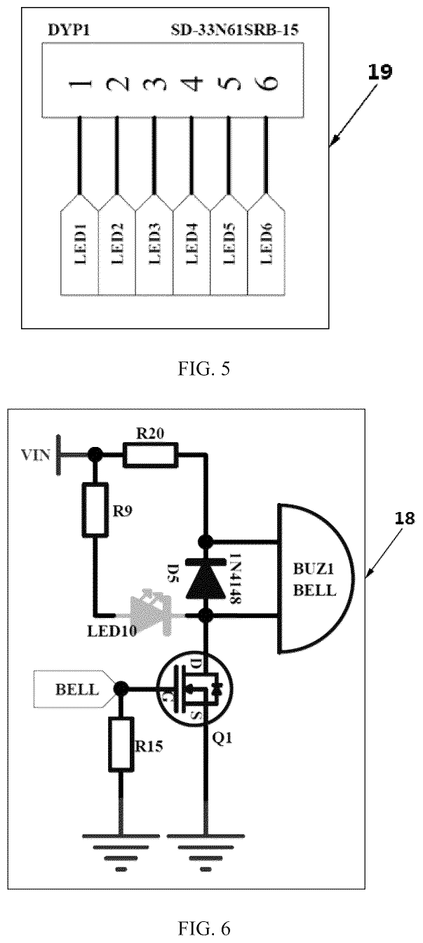

Further, as shown in FIG. 5, the battery terminal protection circuit further includes a voltage display circuit 19. The voltage display circuit 19 is coupled with the main control circuit 11. The voltage display circuit 19 includes a nixie tube with a model of 3661BS, and six sets of input pins of the nixie tube are respectively connected with the pin 8, pin 7, pin 6, pin 5, pin 4, pin 3 and pin 2 of the single-chip computer, so that with provision of the voltage display circuit 19, a voltage value can be displayed by the nixie tube in the voltage display circuit 19 when the voltage detection circuit 13 detects the battery voltage.

Further, as shown in FIG. 6, the battery terminal protection circuit further includes a reverse connection alarm circuit 18. The reverse connection alarm circuit 18 is coupled with the main control circuit 11. The reverse connection alarm circuit 18 includes a triode Q1, a reverse connected light-emitting diode LED 10 and a buzzer. A gate of the triode Q1 is connected with a pin 10 of the single-chip computer, a source of the triode Q1 is grounded, and an input terminal of the reverse connected light-emitting diode LED 10 is connected with a voltage input VIN. An output terminal of the reverse connected light-emitting diode LED 10 is connected with a positive input pin of the buzzer, and a fifth diode D5 is also connected between the positive input pin and a negative output pin of the buzzer, and an output terminal of the reverse connected light-emitting diode LED 10 is further connected with an input terminal of the fifth diode D5, and a drain of the triode Q1 is also connected with the input terminal of the fifth diode D5.

In this way, with provision of the reverse connection alarm circuit 18, the buzzer is set to sound for a long time when the circuit is normally powered on and positive and negative electrodes of the battery terminal are connected correctly, and when the positive and negative electrodes are reversely connected, the reverse connected light-emitting diode LED 10 lights up, and the buzzer can give a fault alarm by flashing at a same frequency until the fault is removed. It should be noted that whistling modes of the buzzer for forward connection and reverse connection can be set or adjusted as desired, which is only an example in this embodiment and is not limited to one of them.

More specifically, principle of realizing reverse connection detection and buzzer alarm by the reverse connection alarm circuit 18 is that when an input power supply is reversely connected, the voltage detection circuit 13 detects a reverse connection signal and transmits it to a detection pin of the single-chip computer, and then the single-chip computer controls to output an alarm signal to the buzzer for warning.

With a reverse connection detection function described above, probability of danger occurring in a process of jumping between automobiles can be reduced.

### Embodiment 2

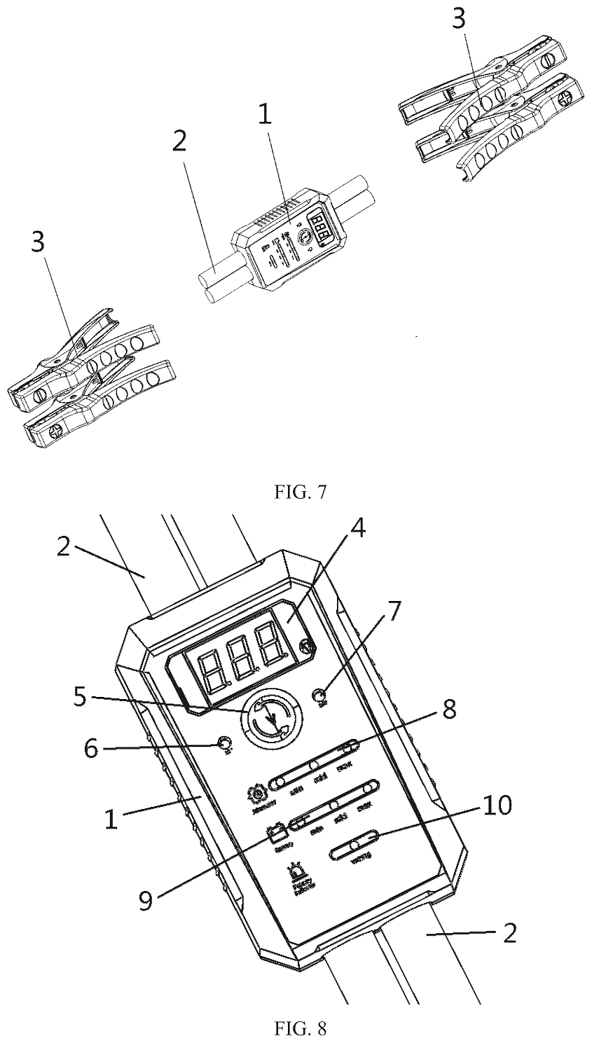

As shown in FIG. 7, a battery terminal includes the battery terminal protection circuit according to Embodiment 1, and further includes a housing 1, a cable 2 and a clamp 3. The housing 1 is arranged on the cable 2, and the battery terminal protection circuit is installed in the housing 1. A set of clamps 3 for positive and negative electrodes are provided at both ends of the cable 2 respectively (connections between the two ends of the cable 3 and the clamps are not shown in FIG. 7, which is in a conventional connection manner), and as shown in FIG. 8, a surface of the housing 1 corresponds to the battery terminal protection circuit in which a voltage display box 4, a voltage mode change-over switch 5, a 12 V voltage display area 6, a 24 V voltage display area 7, an engine health state display area 8, a battery health state display area 9 and a reverse connection alarm display area 10 are provided.

The above is only preferred embodiments of the present disclosure, but not intended to limit the present disclosure in any form or substantially. It should be pointed out that some improvements and supplements can be made by those of ordinary skilled in the art without departing from methods of the present disclosure, which should also be regarded to be within a protection scope of the present disclosure.

Some changes, modifications and equivalent changes can be made by any of technicians who are familiar with the art by using technical content disclosed above without departing from the spirit and scope of this disclosure, which are equivalent embodiments of this disclosure. Meanwhile, any alternations, modifications and evolutions to any equivalent change made to the above-mentioned embodiments according to essential technology of the present disclosure are still within the scope of technical schemes of the present disclosure.

What is claimed is:

1. A battery terminal protection circuit, comprising a main control circuit, a power supply circuit, a voltage detection circuit, a battery state display circuit and an engine state display circuit, wherein the power supply circuit is coupled with the main control circuit and the power supply circuit further provides power supply for the main control circuit; the voltage detection circuit is coupled with the power supply circuit and the voltage detection circuit is further coupled with the main control circuit; the voltage detection circuit is configured to detect voltages of a battery and an engine; and the battery state display circuit and the engine state display circuit are both coupled with the main control circuit.

2. The battery terminal protection circuit according to claim 1, wherein the voltage detection circuit comprises a first resistor, a second resistor and a third resistor, wherein the first resistor is connected in series with the second resistor, and the third resistor is connected in parallel with the second resistor.

3. The battery terminal protection circuit according to claim 1, wherein the battery state display circuit comprises three sets of first light emitting diodes connected in parallel, emitting colors of the three sets of first light emitting diodes being different from each other.

4. The battery terminal protection circuit according to claim 3, wherein the three sets of first light emitting diodes are further connected in parallel with a first voltage mode display circuit.

5. The battery terminal protection circuit according to claim 1, wherein the engine state display circuit comprises three sets of second light emitting diodes connected in parallel, emitting colors of the three sets of second light emitting diodes being different from each other.

6. The battery terminal protection circuit according to claim 5, wherein the three sets of second light emitting diodes are further connected in parallel with a second voltage mode display circuit.

7. The battery terminal protection circuit according to claim 1, further comprising a reverse connection alarm circuit, which is coupled with the main control circuit.

8. The battery terminal protection circuit according to claim 1, further comprising a voltage display circuit, which is coupled with the main control circuit.

9. The battery terminal protection circuit according to claim 1, wherein the main control circuit is further connected with a voltage mode switching circuit.

10. A battery terminal, comprising:
a housing;
a cable;
a clamp; and
a battery terminal protection circuit, comprising a main control circuit, a power supply circuit, a voltage detection circuit, a battery state display circuit and an engine state display circuit, wherein the power supply circuit is coupled with the main control circuit and the power supply circuit further provides power supply for the main control circuit; the voltage detection circuit is coupled with the power supply circuit and the voltage detection circuit is further coupled with the main control circuit; the voltage detection circuit is configured to detect voltages of a battery and an engine; and the battery state display circuit and the engine state display circuit are both coupled with the main control circuit;
wherein the housing is arranged on the cable, the battery terminal protection circuit is installed in the housing, and a set of positive and negative clamps are provided at both ends of the cable respectively.

11. The battery terminal according to claim 10, wherein the voltage detection circuit comprises a first resistor, a second resistor and a third resistor, wherein the first resistor is connected in series with the second resistor, and the third resistor is connected in parallel with the second resistor.

12. The battery terminal according to claim 10, wherein the battery state display circuit comprises three sets of first light emitting diodes connected in parallel, emitting colors of the three sets of first light emitting diodes being different from each other.

13. The battery terminal according to claim 12, wherein the three sets of first light emitting diodes are further connected in parallel with a first voltage mode display circuit.

14. The battery terminal according to claim 10, wherein the engine state display circuit comprises three sets of second light emitting diodes connected in parallel, emitting colors of the three sets of second light emitting diodes being different from each other.

15. The battery terminal according to claim 14, wherein the three sets of second light emitting diodes are further connected in parallel with a second voltage mode display circuit

16. The battery terminal according to claim 10, further comprising a reverse connection alarm circuit, which is coupled with the main control circuit.

17. The battery terminal according to claim 10, further comprising a voltage display circuit, which is coupled with the main control circuit.

18. The battery terminal according to claim 10, wherein the main control circuit is further connected with a voltage mode switching circuit.
